(19) United States
(12) Patent Application Publication
(10) Pub. No.: US 2008/0253423 A1
(43) Pub. Date: Oct. 16, 2008

(54) COMPACT OPTO-ELECTRONIC DEVICE INCLUDING AT LEAST ONE SURFACE EMITTING LASER

(75) Inventor: Christophe KOPP, Fontanil-Cornillon (FR)

Correspondence Address: OBLON, SPIVAK, MCCLELLAND MAIER & NEUSTADT, P.C., 1940 DUKE STREET, ALEXANDRIA, VA, 22314, US

(73) Assignee: COMMISSARIAT A L'ENERGIE ATOMIQUE, Paris (FR)

(21) Appl. No.: 12/100,625

(22) Filed: Apr. 10, 2008

(30) Foreign Application Priority Data
Apr. 13, 2007 (FR) 07 54458

(51) Int. Cl. H01S 5/026

(52) U.S. Cl. 372/50.124; 372/50.21

(57) ABSTRACT

This relates to an opto-electronic device comprising at least two opto-electronic components (1, 2) which work together, including a first one that is a surface light emitting laser (1) and another opto-electronic component (2). Each of the opto-electronic components (1, 2) is mounted on a main face (3.1, 3.2) that is different and opposite an intermediate layer (3) incorporating a grating coupler (5) coupled to an optical wave guide (4) designed to transport part of the light emitted by the surface emitting laser (1). The grating coupler (5) is sandwiched between the emissive face of the surface emitting laser (1) and the other opto-electronic component (2).

### TECHNICAL FIELD

This invention relates to a compact opto-electronic device including at least one Vertical Cavity Surface Emitting Laser or VCSEL, which operates with another opto-electronic component.

It applies in particular to a surface emitting laser with monitoring of the power that it emits or that works with another transmitter to carry out optical multiplexing in an optical wave guide.

The development of surface emitting laser opto-electronic components has opened up a wide range of applications from the detection of gas to the creation of opto-electronic modules for optical fibre networks for short distance networks. The surface emitting lasers have a certain number of advantages compared with edge emitting lasers or EEL, in particular their aptitude to be tested collectively on the common substrate on which they are manufactured and their easier coupling in standard optical fibres.

These surface emitting lasers are used once they are placed in a case, traditionally TO (Transistor Outline) case or TOSA (Transmitter Optical Sub Assembly) cases, respectively fitted with a window allowing the light beam emitted to pass or a device which permits the electrical connection of an optical fibre connector.

### STATE OF THE PRIOR ART

Most applications which use these surface emitting lasers need the power emitted by the laser to be measured constantly, by means of a photo-detector placed inside the case. The photo-detector is typically a PIN type photodiode also called a monitoring photodiode. Therefore the aim is to illuminate the photo-detector with a fraction of the light emitted by the laser before it leaves the case.

Contrary to the edge emitting lasers, it is not possible to place the photo-detector on the face of the laser opposite to that which produces the light as this face is that of a substrate on which the epitaxial growth of the intrinsic structure of the laser has been made and that said substrate is opaque to the light produced by the laser.

The currents required for this monitoring are approximately of the order of 100 to 500 micro amperes with processes capable of detecting very small current variations. Consequently, with photodiodes whose typical sensitivity is less than approximately 1 A/W and surface emitting lasers whose power is around 1 to 2 mW, it may be necessary to sample up to approximately 50% of the light emitted by the laser to monitor it, and the other 50% may be used for the chosen application.

The monitoring is carried out conventionally by using parasite reflections of the light beam emitted by the laser on the outlet window of the case. In fact, a fraction of the beam is reflected and a monitoring photodiode may be placed in the path of the portion of beam after reflection.

In the U.S. Pat. No. 5,905,750, the photo-detector and the emission surface of the laser are next to one another, they are placed substantially in a same plane.

In the patent application GB-A-2 351 180, the laser is mounted on the chip on which the photo-detector is located, wherein the laser and the photo-detector are offset laterally with respect to one another.

In the American U.S. Pat. No. 5,737,348 the laser is mounted on the photo-detector, it is placed in a central zone of the photo-detector. The collection may only be made in a peripheral zone of the photo-detector.

In the patent application WO-A-99/34487 the laser and the photo-detector are fitted as in the patent application GB-A-2 351 180 and the window is inclined with respect to the emission axis of the laser beam so as to redirect the part of the beam that is reflected onto the photo-detector.

In the U.S. Pat. No. 5,943,357 the photo-detector and the laser are stacked on one another and the photo-detector only receives the light emitted by the rear of the laser.

In the American U.S. Pat. No. 5,757,836 the photo-detector is positioned next to the laser, its sensitive face is substantially transversal to the front face of the laser.

In the patent EP-A-0 869 590, the patent application WO-A-03/000019 and the patent application US-A-2003/0109142, the photo-detector is either in the path of the direct beam emitted by the laser, or in the path of a reflected fraction, wherein the front face of the laser and the sensitive face of the photo-detector are in distinct planes.

One disadvantage of these structures is that their base takes up a lot of space, as the photo-detector is positioned laterally to the front face of the laser. This disadvantage also exists in opto-electronic devices comprising a surface emitting laser that is associated to another opto-electronic component that is not a photo-detector but a transmitter. Such an opto-electronic device further comprises a multiplexer to combine the beams emitted by the two sources of light and carry out multiplexing.

The last three structures mentioned are also quite thick.

The structures on which the monitoring is carried out on a fraction of the beam emitted by the laser, wherein this fraction is reflected by a window, are not satisfactory as the power monitored is not high enough and the signal to noise ratio is too low.

Furthermore, when the device comprises several lasers in a same case, and the monitoring is made on reflected beams, it is not possible to discriminate between the respective powers of the different lasers.

### DESCRIPTION OF THE INVENTION

The purpose of this invention is precisely to propose an opto-electronic device that does not have the disadvantages mentioned above.

One purpose is in particular to propose such an opto-electronic device that is very compact with respect to the prior art.

Another purpose of this invention is to propose an opto-electronic device that comprises a surface emitting laser that operates together with a component that is a monitoring photo-detector, in which the power that is monitored by the photo-detector is increased with respect to the prior art, wherein this monitoring permits any dysfunctioning laser to be detected and/or to regulate the mean power emitted.

Another purpose of the invention is to provide an opto-electronic device with a surface emitting laser that operates together with a photo-detector in which the representativity of the power level is increased with respect to the prior art.

To achieve these purposes the invention concerns more precisely an opto-electronic device comprising at least two opto-electronic components which work together, among which a first one that is a surface light emitting laser and another opto-electronic component, characterised in that each of the opto-electronic components is mounted on a main face that is different and opposite an intermediate layer incorporating a grating coupler coupled to an optical wave guide designed to transport part of the light emitted by the surface emitting laser, wherein the grating coupler is sandwiched between the emissive face of the surface emitting laser and the other opto-electronic component.

The other opto-electronic component may be a photo-detector for monitoring the light emitted by the laser.

As a variant, the other opto-electronic component may be a transmitter designed to carry out multiplexing with the surface emitting laser.

The grating coupler is semi-transparent for the light emitted by the surface emitting laser, especially when the other opto-electronic component is a photo-detector.

The intermediate layer may be flanked on each of its main faces by electrical connection tracks.

At least one electrical connection track is ended with a pad fitted with a collapse chip before the laser or the other opto-electronic component is mounted.

An electrical connection track of a face of the intermediate layer may be connected to an electrical connection track on the other face of the intermediate layer by at least one metallised hole passing through the intermediate layer.

A case may accommodate the intermediate layer and at least one pair formed by the laser and the other opto-electronic component.

When several pairs are accommodated in the case, the opto-electronic components mounted on one face of the intermediate layer may be individual or grouped into linear array.

This invention also concerns a manufacturing process for an opto-electronic device comprising at least two opto-electronic components which work together including a first component that is a surface light emitting laser and another opto-electronic component comprising the following steps:
creation on a base substrate of an intermediate layer incorporating a grating coupler coupled to an optical wave guide with a free main face,
creation of electrical connection tracks on the free main face of the intermediate layer,
assembly of one of the two opto-electronic components on the free main face of the intermediate layer by positioning it at the level of the network coupler and by connecting it electrically to the electrical connection tracks,
depositing of a coated material on the free main face of the intermediate layer incorporating the assembled opto-electronic component,
elimination of the base substrate to reveal another main face of the intermediate layer,
creation of electrical connection tracks on the revealed main face of the intermediate layer,
assembly of the other opto-electronic component on the revealed main face of the intermediate layer positioning at the level of the network coupler and by connecting it electrically to the electrical connection tracks of the revealed main face.

In the process, the assembly may use collapse chip connection, thermo-compression of pads or bonding with conductive glue.

Glue may be inserted between the intermediate layer and at least one of the opto-electronic components.

The grating coupler and the optical wave guide may be made on the surface of the base substrate.

The optical wave guide may have a core which is made, like the grating coupler, from silicon, doped silica, a material obtained by sol-gel, resin, polymer.

The base substrate may be eliminated by selective chemical etching.

### BRIEF DESCRIPTION OF THE DRAWINGS

This invention will be more clearly understood upon reading the description of examples of embodiments provided, purely by way of illustration and in no way restrictively, in reference to the appended drawings in which:

FIG. 1 shows a cross section of an example of an opto-electronic device according to the invention;

FIGS. 2A, 2B, 2C show, in a top view and/or a bottom view opto-electronic devices of the invention accommodated in a case;

FIGS. 3A to 3H show examples of steps for creating the intermediate layer, conductive tracks and bond pads of the opto-electronic device of the invention;

FIGS. 4A to 4I show examples of hybridisation steps of an opto-electronic component of the opto-electronic device of the invention;

FIGS. 5A to 5D show examples of hybridisation steps of the other opto-electronic component of the opto-electronic device of the invention.

Identical, similar or equivalent parts of the various figures described below bear the same numerical references so as to facilitate switching from one figure to another.

The different parts shown in the figures are not necessarily to a uniform scale, to make the figures easier to read.

It is to be understood that the different variants shown are not necessarily mutually exclusive.

Structures that are found in the prior art are not shown in detail in order to avoid this invention more difficult to be read.

### DETAILED DESCRIPTION OF SPECIFIC EMBODIMENTS

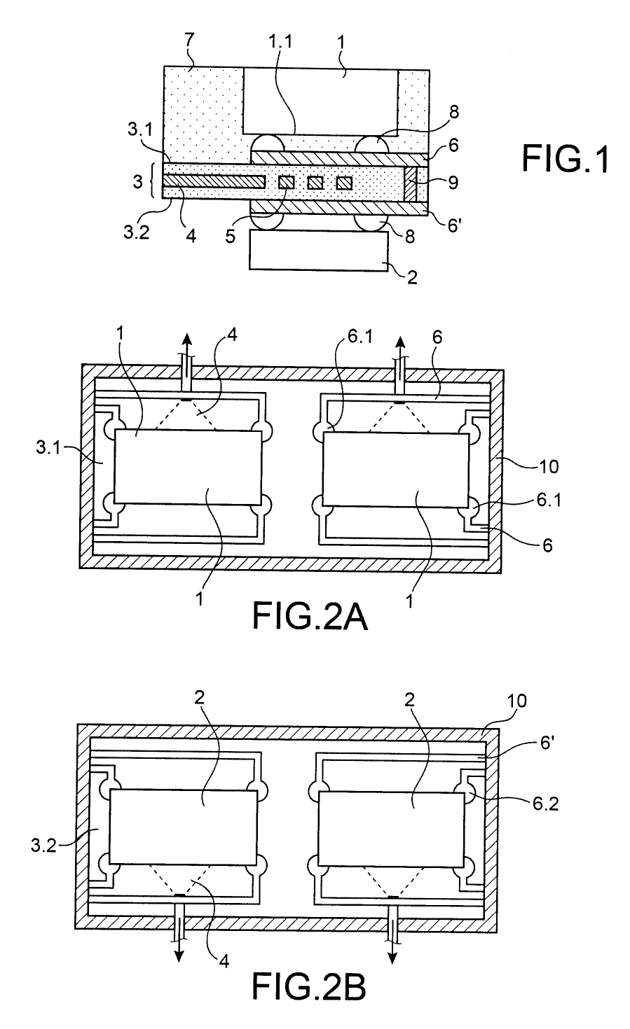

FIG. 1 shows an opto-electronic device with two opto-electronic components including a surface light emitting laser and another opto-electronic component. The laser has the reference 1 and the other opto-electronic component 2. The two opto-electronic components 1, 2 work together with one another. The other opto-electronic component 2 may be a monitoring photo-detector, for example a PIN diode, or an optical transmitter, for example another surface emitting laser, a diode laser or other.

In the following description, other opto-electronic components 2 will be mentioned in general.

The surface emitting laser 1 and the other opto-electronic component 2 are mounted on either side of an intermediate layer 3 incorporating an optical wave guide 4 and a grating coupler 5. The face of the laser 1 which emits the light has the reference 1.1, it is located on the intermediate layer 3 side.

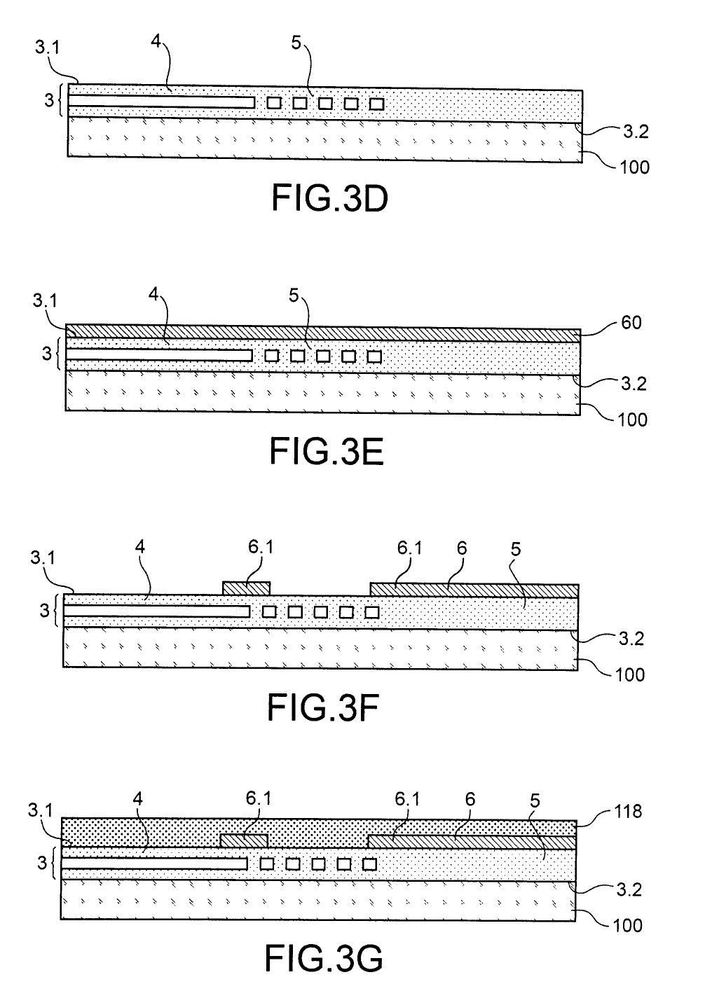

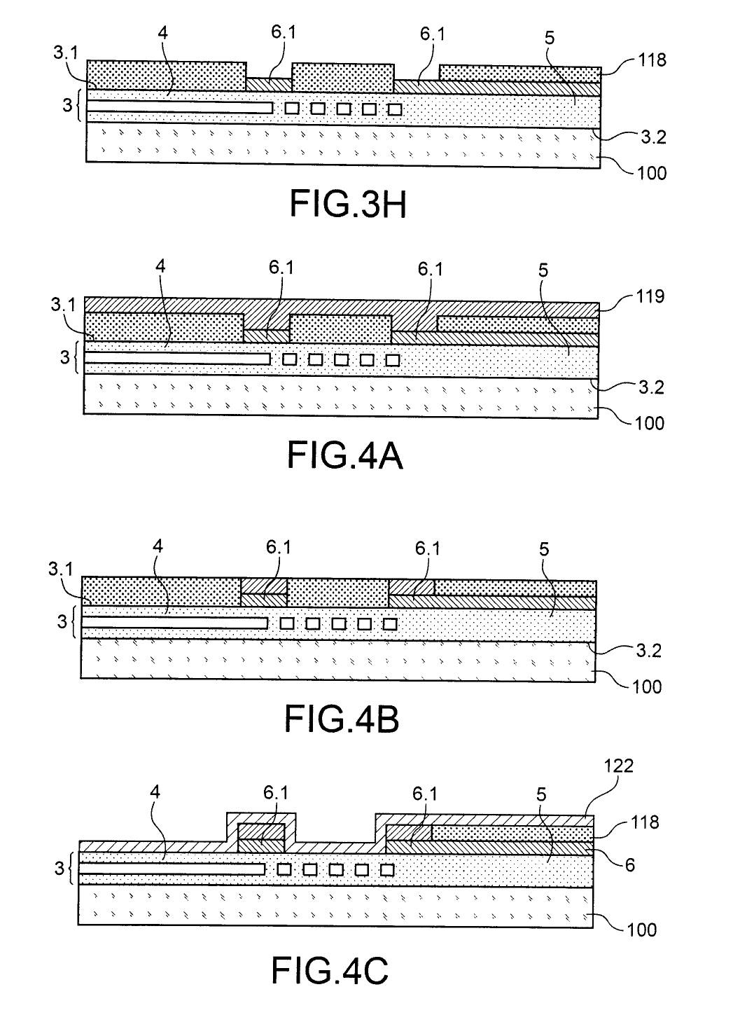

The optical wave guide 4 is designed to transport part of the light emitted by the surface emitting laser 1 to a user device (not shown). The optical wave guide 4 has one end coupled to the grating coupler 5 and one free end from which the light transported by the optical wave guide 4 leaves. The grating coupler 5 is positioned upstream of the optical wave guide 4, opposite the emitting face 1.1 of the laser 1. The grating coupler 5 may be for example a diffraction network, a Bragg's grating or other. The network couplers are known as optical structures. They feature a periodic network type structure which permits part of the light they receive to be injected substantially perpendicularly or inclined into the optical wave guide that is coupled to them and which is located in the extension of the grating coupler, substantially in the same plane. The periodic structure can be seen clearly in FIG. 3B. Reference may be made to the article “Silicon-on-insulator nanophotonics by W. Boagerts et al. Proceedings of SPIE, Integrated Optics: Theory and Applications, 31 Aug. 2005 to 2 Sep. 2005, Warsaw, Poland, T. 2005, Vol. 5956”, which shows grating couplers for the light coupling in an optical wave guide. The other part of the light emitted by the laser 1 passes through the grating coupler 5 which is semi-transparent, and reaches the other opto-electronic component 2. If it is a photo-detector, the latter may monitor the emission of the laser 1. If the other opto-electronic component 2 is a transmitter, the grating coupler 5 is also semi-transparent.

Typically the coupling rate of the light emitted by the laser 1 in the optical wave guide 4 is approximately 50 to 80%.

When the other opto-electronic component 2 is another surface emitting laser, it is symmetrical to the first laser 1 with respect to the grating coupler 5. Its face which emits the light is opposite the grating coupler 5.

Reference 7 shows a coated material which surrounds the surface emitting laser 1. Its use will be described below.

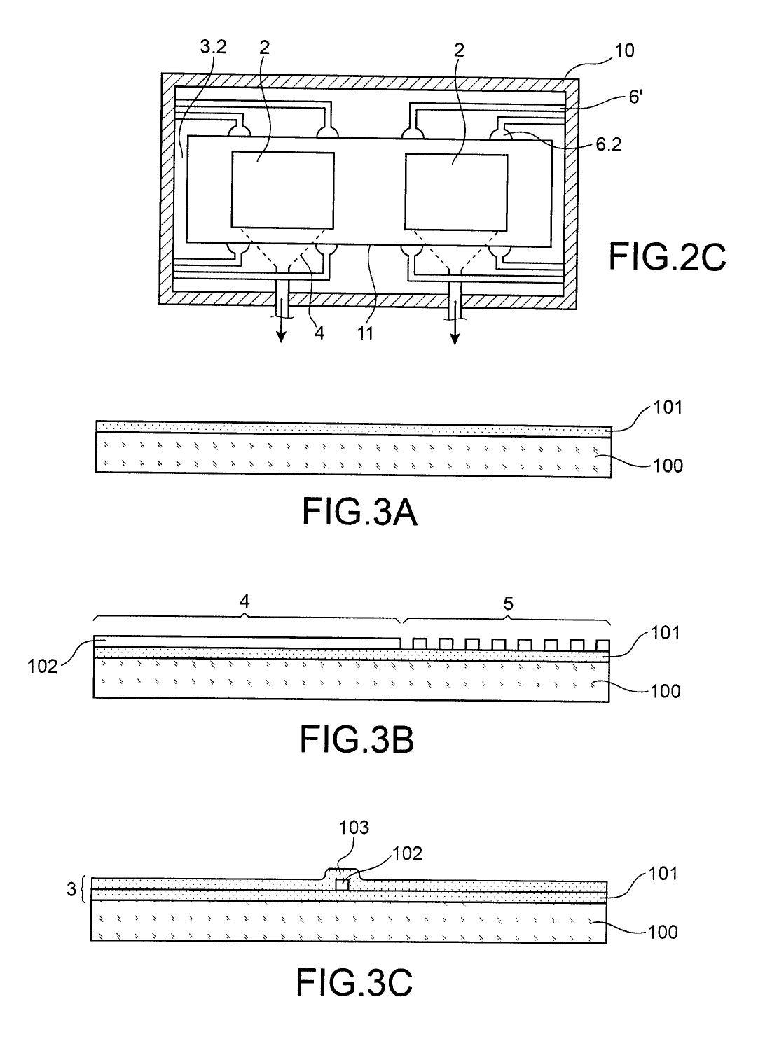

The surface emitting laser 1 and the other opto-electronic component 2 are mounted or hybridised onto the intermediate layer 3, sandwiching the grating coupler 5. The assembly may use collapse chips 8 with a fusible material to be applied onto the bond pads 6.1, 6.2 (visible in FIGS. 2) or conductive tracks 6, 6′, this assembly technique is known as the “flip chip” assembly technique, or connection by collapse chips, or C4 by IBM, where C4 is the acronym of “Controlled Collapse Chip Connection”.

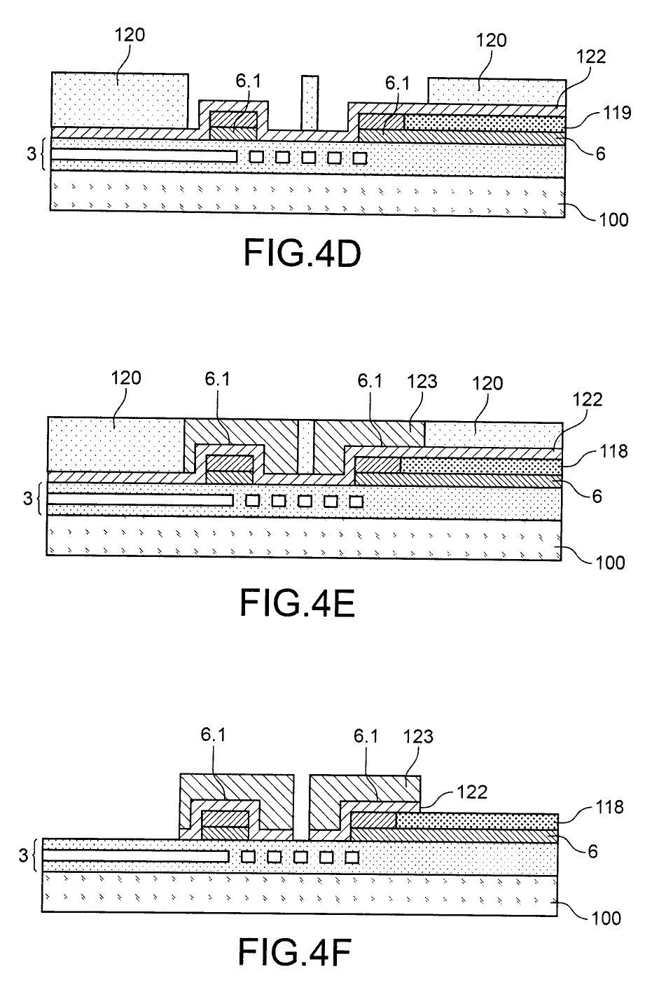

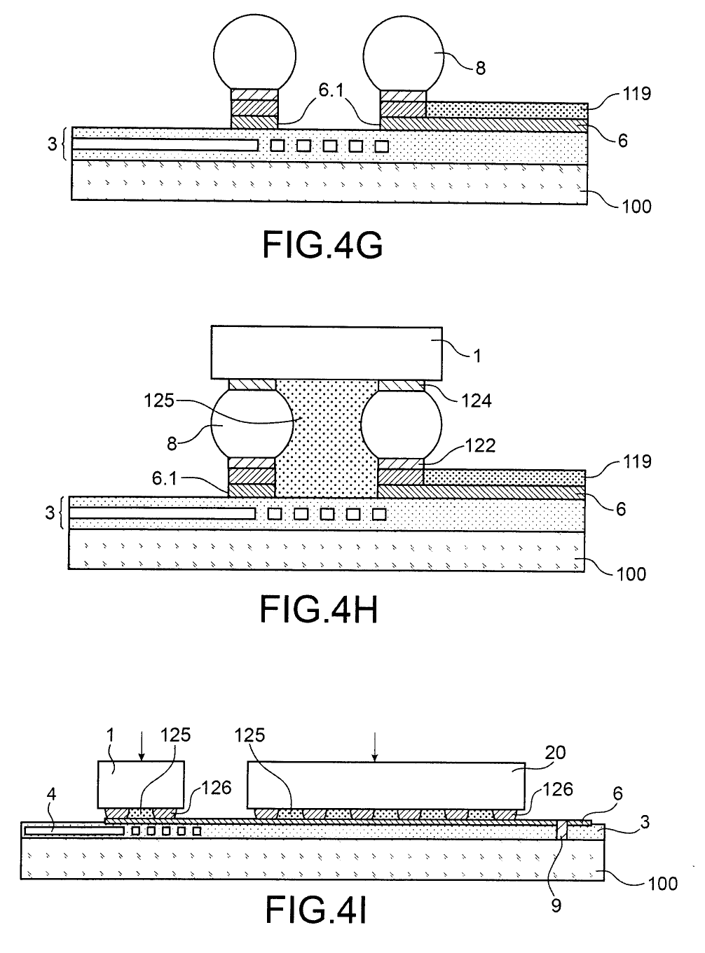

As a variant, it is possible to thermo-compress connector metallic pads 126 or bond using conductive resin pins deposited for example by screen printing. It is supposed that in FIG. 4I, the pads 126 indifferently show metallic pads or conductive resin pads.

The collapse chips 8 may be carried either by the laser or by the other opto-electronic component or by the intermediate layer 3 prior to hybridisation.

The surface emitting laser 1 and the other opto-electronic component 2 need to be connected to electrical connection tracks 6, 6′ for their energy supply and for their command or to collect the electrical signals that they generate in the case of a photo-detector 2. It is provided that on each of the main faces 3.1, 3.2 of the intermediate layer 3 on which the surface emitting laser 1 and the other opto-electronic component 2 are mounted, these conductive tracks are fitted, for example fitted out in a network. An electrical connection track 6 of one face 3.1 may be connected to a electrical connection track 6′ of the other face 3.2 by means of a metallised hole 9 or via. These electrical connection tracks 6, 6′ may be ended with bond pads 6.1, 6.2 on which the collapse chips 8 are made for the hybridisation of the surface emitting laser 1 and the other opto-electronic component 2.

The intermediate layer 3 may be made from a silicon or silica base for example, as will be described below.

The opto-electronic device that is the subject of the invention is especially well suited to the case where it comprises, in a same case 10, several surface emitting lasers 1 which work together each with an opto-electronic component 2 of the photo-detector type. Each of the photo-detectors 2 monitors the power emitted by the laser 1 that operates together with it through the intermediate layer 3. The lasers 1 and the opto-electronic components 2 may be presented unitarily and be assembled individually on the intermediate layer 3 as illustrated in FIGS. 2A, 2B or be presented grouped together in linear array 11 as illustrated in FIG. 2C. FIG. 2A is a top view of the opto-electronic device on the laser 1 side, whereas FIGS. 2B, 2C are bottom views of the opto-electronic device, which is to say on the side of the other opto-electronic component 2. The case 10, the electrical connection tracks 6 or 6′ and the bond pads 6.1 or 6.2 are visible in this view. The optical wave guide 4 is sketched.

Based on FIGS. 2A, 2B, it is possible to place inside the case 10, in parallel, twelve lasers 1, each emitting a multimode beam, wherein these beams all have the same preferred direction. These lasers 1 may be surface emitting lasers in gallium arsenide with a wavelength of 850 nanometres. This corresponds to the SNAP 12 standard based on a common standard for pluggable 12 channel optical fibres modules. The optical outputs of the opto-electronic device according to the invention may be directly coupled in the multimode optical wave guides of the printed optical circuits for connections between boards.

Now an example of the manufacturing process of an opto-electronic device of the invention will be examined.

Using a base substrate 100, for example made of silicon, on which the optical wave guide 4 and the grating coupler 5 are to be formed. This formation is made by a series of steps for depositing or forming and micro structuring. If the optical wave guide 4 is made on the surface, it is possible to start by depositing, on the base substrate 100, for example by Plasma enhanced chemical vapour deposition—PECVD—a lower cladding layer 101, for example made of silica, for the optical wave guide (FIG. 3A). Then the core 102 of the optical wave guide is made by depositing, for example by PECVD, a layer of silicon, silica doped with phosphorous, boron or germanium for example, resin or polymer. In this way the contours of the core 102 are defined by photolithography followed by etching (FIG. 3B). At the same time, the patterns of the grating coupler 5 are defined at the end of the core 102. Next is deposited, for example by PECVD a second cladding layer 103, for example in silica, on the core 102, the grating coupler 5 and the first cladding layer 101 (FIG. 3C). FIG. 3C is a transversal cross section of the optical wave guide 4 and FIG. 3D is a longitudinal cross section. It is also possible to make from a semi-conductor on insulator substrate known as SOI or silicon-on-insulator as described in the article mentioned above.

For multimode optical wave guide applications, the optical wave guides of which at least the core is obtained by the sol-gel, resin and polymer process are preferred.

The intermediate layer 3 is thus created. It has a main face 3.1 that is free and another main face 3.2 that is attached to the base substrate 100 and that will be subsequently revealed.

Then on the free main face 3.1 of the intermediate layer 3, the electrical connection tracks 6 are created that are appropriated to the opto-electronic component that will be assembled to this free face 3.1 of the intermediate layer 3, and possibly the bond pads 6.1 which end these electrical connection tracks 6 and are used for the assembly of the opto-electronic component. The opto-electronic component may be the surface emitting laser 1 but it may be envisaged that it is the other opto-electronic component 2 that is assembled onto this free face 3.2. In the following description, it is supposed that it is the laser that is to be assembled first but this is not restrictive.

The electrical connection tracks 6 may be made conventionally with a metal base such as aluminium, which is the most commonly used metal, copper, gold or silver for example by PVD—plasma vapour deposition. The metal 60 is deposited by photolithography and etching is used to define the contour of the electrical connection tracks 6 and that of the bond pads 6.1 (FIGS. 3E, 3F).

This assembly is then covered by an electrically insulating passivation layer 118, for example SiO₂ or Si₃N₄, by PECVD (FIG. 3G). This insulating passivation layer 118 is etched at the pads 6.1 so as to reveal them (FIGS. 3H). The etching may be of the RIE type (acronym for reactive ion etching) for example. If thermo-compression assembly is used, then the process stops here as no collapse chips are used.

It is supposed that in the example described, the tracks 6 are made at the same time as the pads 6.1 fitted with collapse chips 8.

Now we will cover the creation of connector pads 6.1 equipped with collapse chips 8 to assemble the laser 1 onto the intermediate layer 3 by collapse chip connection (flip-chip process). By calling the collapse chips “fusible”, this means that they are made from a material that can melt at temperatures that are low enough to avoid damaging the component to be assembled using collapse chips.

The bond pads 6.1 equipped with collapse chips 8 are positioned either on the surface of the intermediate layer 3, or on the laser 1 or on the other opto-electronic component 2. If they are made on the intermediate layer 3, they are placed in electrical contact with the electrical connection tracks 6, 6′.

When assembling, the emissive face of the laser 1 is opposite the grating coupler 5. As concerns the other opto-electronic component 2, if it is a photo-detector, its sensitive face is opposite the grating coupler 5 and if it is a transmitter, it is its emissive face that is opposite the grating coupler 5.

The opto-electronic component 1, 2 also comprises bond pads that may or may not be equipped with collapse chips, as the collapse chips 8 are located either on the intermediate layer 3 or on the opto-electronic component 1, 2 prior to the hybridisation.

In the example described in FIGS. 3 and 4, it is supposed that the pads 6.1 equipped with collapse chips 8 are made on the intermediate layer 3. This is not restrictive, the process would be the same to make them on the component. It is supposed that at the electrical connection tracks 6 are made at the same time as the bond pads 6.1. On the pads 6.1 of the intermediate layer 3, a deposit tie layer 119 of metal is formed, that is generally multilayer for example a multilayer titanium-nickel-gold (FIG. 4A). Using photolithography followed by etching (FIG. 4B) in the tie metal 119, the tie metal 119 will be defined at the contour of the bond pads 6.1. It is supposed that the right hand bond pads 6.1 is on the end of the single electrical connection track 6 visible in FIGS. 4. There is another bond pads 6.1 on the left hand side.

The collapse chips 8 are made at the level of the connector pads 6.1. A continuous base 122 is deposited on the surface (FIG. 4C), for example made of titanium using PVD. It acts as the electrical contact for depositing by electrolysis.

Photolithography is then used to make recesses using the resin 120, at the level of the connector pads 6.1, which are to hold the fusible material of the collapse chips (FIG. 4D).

The recesses are filled with fusible material 123 (FIG. 4E), which may be achieved using electrolytic growth. The material may be for example a lead-tin alloy, or indium. After solidification, the recesses 120 are eliminated, as are the continuous base material 122, which is made accessible by the elimination of the recesses (FIG. 4F). This is heated so as to obtain the melting of the fusible material 123 and thus group it in the form of collapse chips 8 (FIG. 4G).

The hybridised laser 1 also comprises metallic bond pads which need to be attached to the collapse chips 8. They have the references 124 on FIG. 4H. By heating and re-melting the fusible material of the collapse chips 8, a mechanical and electrical connection is created between the laser 1 and the intermediate layer 3 at the level of the electrical connection tracks 6 on it (FIG. 4H). Once the collapse chips have solidified 8, the surface tension of the fusible material causes automatic alignment of the laser 1 with respect to the bond pads 6.1 of the intermediate layer 3. The collapse chips 8 provide both the mechanical positioning and the electrical connection of the laser 1 thus attached. The use of the flip chip technique and collapse chip connection is used for its good hyper-frequency performances and for its self-alignment properties, which are accurate to within a few microns or even less than a micron. Consequently the passive alignment of the laser 1 and the intermediate layer 3 are achieved.

It is possible to attach another component 20 to the same free face 3.1 of the intermediate layer 3 as that which accommodates the laser 1. This may be for example a piloting device 20 for the laser 1 shown in FIG. 4I. The above description concerns the mounting of the laser 1 but the same process may also be used to mount the other opto-electronic component 2 on the other main face of the intermediate layer. This is why this will not be described and illustrated again.

Instead of using a traditional collapse chip connection technique, an assembly technique using metallic pads 126 and thermo-compression may be used as illustrated in FIG. 4I.

In both cases, glue 125 may be added between the laser 1 and the intermediate layer 3 to avoid problems of thermal expansion.

As a variant, it is possible that bond pads made of electrically conductive resin are used for the assembly instead of using metallic pads and possibly the collapse chips. These resins may be loaded with silver, palladium or platinum for example. Transparent glue may also be placed between the laser and the intermediate layer.

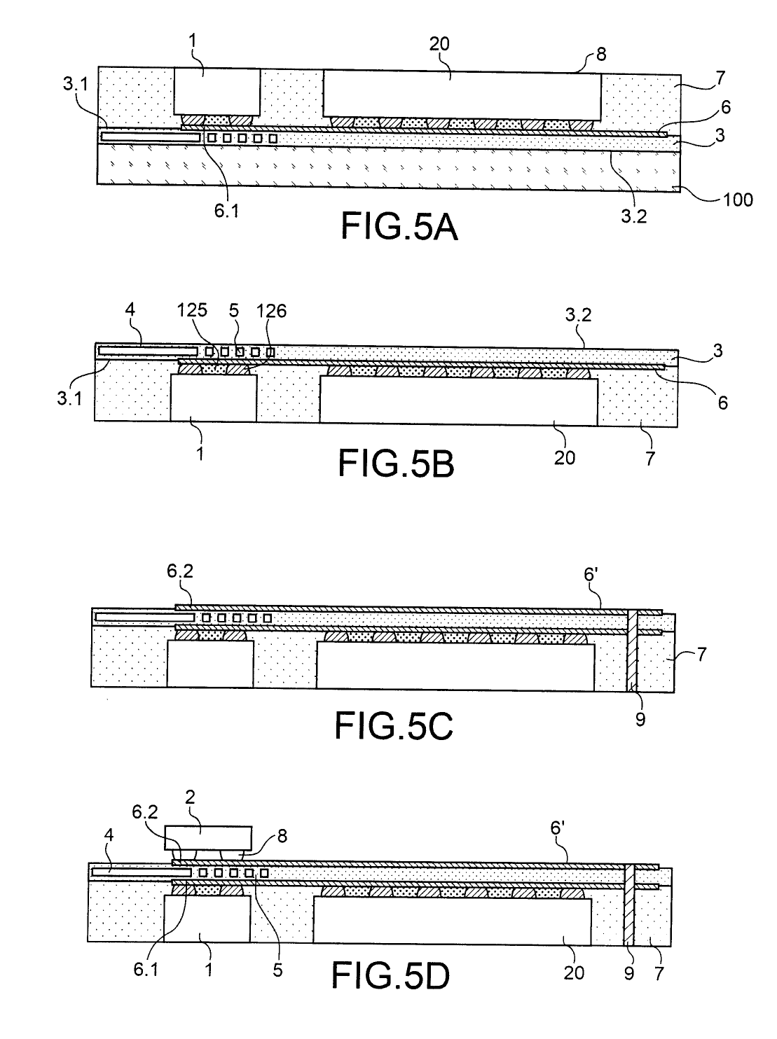

FIG. 5A illustrates a step for coating the components 1, 20 assembled on the free face 3.2 of the intermediate layer 3. This coating process uses a coating material 7 for example resin. The coating material 7 covers the free face 3.1 of the intermediate layer and surrounds the component 1 and the piloting device 20. This coating material 7 helps to stiffen the intermediate layer 3 so that its other main face 3.2 may be revealed by eliminating the base substrate 100. If the base substrate 100 is made of silicon, it may be eliminated by selective chemical etching stopping at the intermediate layer 3 (FIG. 5B). On the revealed main face 3.2 of the intermediate layer 3, for example in the same manner as described above, electrical connection tracks 6′ are created which end with pads 6.2 to accommodate the other opto-electronic component 2 (FIG. 5C). These pads 6.2 may be fitted with collapse chips 8 as previously described. As a variant, the collapse chips 8 may be attached to the component 2 instead of being attached to the intermediate layer 3. The other opto-electronic component 2 is then attached at the planned positions (FIG. 5D).

It is possible to provide an interconnection between the electrical connection tracks 6 of one of the main faces 3.1 of the intermediate layer 3 and the electrical connection tracks 6′ of the other main face 3.2 of the intermediate layer 3. This interconnection may be achieved by means of metallised holes 9 which pass through the thickness of the intermediate layer 3. These metallised holes may be formed prior to the coating step (FIG. 4I) or after the step which reveals the other main face 3.2 of the intermediate layer 3 (FIG. 5C). The metallised holes are made using traditional microelectronic techniques. In FIGS. 5, only two bond pads 6.1, 6.2 are illustrated at the end of the electrical connection tracks 6 and 6′.

With such a manufacturing process, it is possible to manufacture opto-electronic devices of the invention, collectively by using the usual micro-electronic means and to obtain the accuracy required for this type of opto-electronic device.

Even though several embodiments of this invention have been shown and described in detail, it can be understood that various changes and modifications may be made without this leaving the scope of the invention. It is especially possible to hybridise the opto-electronic components by all means familiar to a person skilled in the art.

1. Opto-electronic device comprising at least two opto-electronic components (1, 2) which work together, including a first one that is a surface light emitting laser (1) and another one that is an opto-electronic component (2), characterised in that each of the opto-electronic components (1, 2) is mounted on a main face (3.1, 3.2) that is different and opposite an intermediate layer (3) incorporating a grating coupler (5) coupled to an optical wave guide (4) designed to transport part of the light emitted by the surface emitting laser (1), wherein the grating coupler (5) is sandwiched between the emissive face of the surface emitting laser (1) and the other opto-electronic component (2).

2. Opto-electronic device according to claim 1, characterised in that the other opto-electronic component (2) is a photo-detector for monitoring the light emitted by the laser (1).

3. Opto-electronic device according to claim 1, characterised in that the other opto-electronic component (2) is a transmitter.

4. Opto-electronic device according to any of claims 1 to 3, characterised in that the grating coupler (5) is semi-transparent for the light emitted by the surface emitting laser (1).

5. Opto-electronic device according to any of the previous claims, characterised in that the intermediate layer (3) is flanked on each of its main faces (3.1, 3.2) by electrical connection tracks (6, 6′).

6. Opto-electronic device according to claim 5, characterised in that at least one electrical connection track (6) ends with a pad (6.1) equipped with a collapse chip (8) prior to the laser (1) or the other opto-electronic component (2) being mounted.

7. Opto-electronic device according to any of claims 5 or 6, characterised in that an electrical connection track (6) on one face (3.1) is connected to a electrical connection track (6′) on the other face (3.2) by at least one metallised hole (9) which passes through the intermediate layer (3).

8. Opto-electronic device according to any of the previous claims, characterised in that a case (10) accommodates the intermediate layer (3) and at least one pair formed by the laser (1) and the other opto-electronic component (2).

9. Opto-electronic device according to claim 8, characterised in that when several pairs are accommodated in the case (10), the opto-electronic components (1) mounted on a face of the intermediate layer (3) are individual or grouped into linear array (11).

10. Manufacturing process of an opto-electronic device comprising at least two opto-electronic components (1, 2) which work together including a first which is a surface light emitting laser (1) and another opto-electronic component (2) comprising the following steps:
creation on a base substrate (100) of an intermediate layer (3) incorporating a grating coupler (5) coupled to an optical wave guide (4) with a free main face (3.1),
creation of electrical connection tracks (6) on the free main face (3.2) of the intermediate layer (3),
assembly of one of the two opto-electronic components (1) on the free main face (3.1) of the intermediate layer (3) by positioning it at the level of the network coupler (5) and by connecting it electrically to the electrical connection tracks (6),
depositing of a coating material (7) on the free main face (3.1) of the intermediate layer (3) which covers the assembled opto-electronic component (1),
elimination of the base substrate (100) to reveal another main face (3.2) of the intermediate layer (3),
creation of electrical connection tracks (6′) on the revealed main face (3.2) of the intermediate layer (3),
assembly of the other opto-electronic component (2) on the revealed main face (3.2) of the intermediate layer (3) by positioning it at the level of the network coupler (5) and by connecting it electrically to the electrical connection tracks (6′) of the revealed main face (3.2).

11. Process according to claim 10, characterised in that the assembly is made using collapse chip connection (8), thermo-compression of pads (126) or by bonding with conductive glue.

12. Process according to claim 11, characterised in that the glue (125) is inserted between the intermediate layer (3) and at least one of the opto-electronic components (1, 2).

13. Process according to any of claims 10 to 12, characterised in that the grating coupler (5) and the optical wave guide (4) are made on the surface of the base substrate (100).

14. Process according to any of claims 10 to 13, characterised in that the optical wave guide (4) has a core (102) that is made, as is the grating coupler (5), from silicon, doped silica, a material obtained by sol-gel, resin or polymer.

15. Process according to any of claims 10 to 14, characterised in that the base substrate (100) is eliminated by selective chemical etching.
